(19) United States
(12) Patent Application Publication
(10) Pub. No.: US 2010/0320453 A1
(43) Pub. Date: Dec. 23, 2010

(54) THIN-FILM TRANSISTOR AND METHOD FOR PRODUCING THE SAME

(75) Inventors: Masanobu Tanaka, Kanagawa (JP); Hirotsugu Ishihara, Tokyo (JP); Haijing Chen, Kanagawa (JP); Kenichi Kurihara, Kanagawa (JP)

Correspondence Address: SNR DENTON US LLP, P.O. BOX 061080, CHICAGO, IL, 60606-1080, US

(73) Assignee: SONY CORPORATION, Tokyo (JP)

(21) Appl. No.: 12/797,053

(22) Filed: Jun. 9, 2010

(30) Foreign Application Priority Data
Jun. 22, 2009 (JP) 2009-147783

(51) Int. Cl. H01L 51/10; H01L 51/40

(52) U.S. Cl. 257/40; 438/99; 257/E51.006

(57) ABSTRACT

A thin-film transistor includes a gate electrode disposed on a substrate, a semiconductor layer formed of an organic semiconductor and constituting a channel region, a gate insulating film disposed between the gate electrode and the semiconductor layer, and a pair of source/drain electrodes electrically connected to the semiconductor layer. The semiconductor layer includes a protruding portion protruding toward the substrate from an inner region of a surface, opposite the substrate, of the semiconductor layer excluding a region near ends thereof.

### BACKGROUND OF THE INVENTION

1. Field of the Invention

The present invention relates to thin-film transistors including a semiconductor layer of an organic semiconductor material and methods for producing the thin-film transistors.

2. Description of the Related Art

Nowadays thin-film transistors (TFTs) including a semiconductor layer (channel layer) of an organic semiconductor material have increasingly been developed for application to flexible film displays.

TFTs using amorphous silicon and polysilicon are costly to produce because a film deposited over an entire substrate by vacuum deposition is etched by photolithography. The use of an organic semiconductor significantly reduces the cost because a semiconductor layer can be handled in liquid form and can therefore be formed by a low-cost process such as printing. Methods for printing a liquid semiconductor include inkjet printing, screen printing, and ink sliding.

For inkjet printing, Japanese Unexamined Patent Application Publication No. 2006-167696 discloses a method for assisting in fine patterning by forming surface-fluorinated lyophobic structures called banks on a gate insulating film.

### SUMMARY OF THE INVENTION

In practice, however, it is difficult to accurately form a fine pattern by the above inkjet method. To form an excellent semiconductor pattern, the wettability of the liquid organic semiconductor to the gate insulating film inside the banks should be sufficiently high, and a low surface tension should be maintained throughout drying and annealing steps; otherwise, the ends of the organic semiconductor pattern would be poorly defined, and it would therefore be difficult to form a desired shape. On the other hand, Japanese Unexamined Patent Application Publication No. 2007-250842 discloses a technique for forming an excellent pattern by partially deforming a gate insulating film so as to form recesses and forming organic semiconductor layers in the recesses.

However, if the organic semiconductor layers are formed in the recesses on the gate insulating film, as described above, projections are formed at the ends (peripheries) of the organic semiconductor layers in a step of drying the organic semiconductor layers. These projections have a problem in that they may disconnect source and drain electrodes formed thereon.

Accordingly, it is desirable to provide a method for producing a thin-film transistor in which a fine pattern of semiconductor layer can be formed using an organic semiconductor material while inhibiting formation of projections at the ends thereof and also to provide such a thin-film transistor.

A method for producing a thin-film transistor according to an embodiment of the present invention is a method for producing a bottom-gate thin-film transistor. This method includes the steps of forming a gate electrode and a gate insulating film on a substrate in the stated order; forming a lyophobic layer on the gate insulating film, forming a first opening in the lyophobic layer, and forming a recess having the same size as the first opening in the gate insulating film; forming a second opening in the lyophobic layer by widening the first opening; forming a semiconductor layer of a liquid organic semiconductor in the recess of the gate insulating film and the second opening of the lyophobic layer; drying the semiconductor layer and removing the lyophobic layer; and forming a pair of source/drain electrodes in contact with the semiconductor layer.

A method for producing a thin-film transistor according to another embodiment of the present invention is a method for producing a top-gate thin-film transistor. This method includes the steps of forming a buffer layer of an insulating material on a substrate; forming a lyophobic layer on the buffer layer, forming a first opening in the lyophobic layer, and forming a recess having the same size as the first opening in the buffer layer; forming a second opening in the lyophobic layer by widening the first opening; forming a semiconductor layer of a liquid organic semiconductor in the recess of the buffer layer and the second opening of the lyophobic layer; drying the semiconductor layer and removing the lyophobic layer; forming a gate insulating film on the buffer layer and the semiconductor layer; and forming a pair of through-holes reaching the semiconductor layer in the gate insulating film and forming a pair of source/drain electrodes in contact with the semiconductor layer via the through-holes.

According to the above methods for producing a thin-film transistor, the lyophobic layer is formed on the gate insulating film (or the buffer layer), the recess is formed in the gate insulating film (or the buffer layer), and the opening (first opening) of the lyophobic layer is made larger than the recess (that is, the second opening is formed). Accordingly, the semiconductor layer formed thereafter is thicker in the inner region thereof and is thinner near the ends (periphery) thereof. In addition, a lyophilic region is provided in a region inside the second opening, including the bottom and side surfaces of the recess and a region surrounding the recess, by the gate insulating film (or the buffer layer), and a lyophobic region is provided in the other region by the lyophobic layer. This allows formation of a pattern of semiconductor layer corresponding to the planar shape of the lyophilic region and inhibits formation of projections at the ends of the semiconductor layer in a step of drying the semiconductor layer.

A thin-film transistor according to an embodiment of the present invention can be formed by the above methods. That is, the thin-film transistor includes a gate electrode disposed on a substrate, a semiconductor layer formed of an organic semiconductor and constituting a channel region, a gate insulating film disposed between the gate electrode and the semiconductor layer, and a pair of source/drain electrodes electrically connected to the semiconductor layer. The semiconductor layer includes a protruding portion protruding toward the substrate from an inner region of a surface, opposite the substrate, of the semiconductor layer excluding a region near ends thereof.

More specifically, if the above thin-film transistor is a bottom-gate thin-film transistor, the gate electrode, the gate insulating film, and the semiconductor layer are disposed in order from the substrate, and a recess is provided in a region of the gate insulating film opposite the semiconductor layer such that the protruding portion is disposed in the recess. If the above thin-film transistor is a top-gate thin-film transistor, it further includes a buffer layer, the buffer layer, the semiconductor layer, the gate insulating film, and the gate electrode are disposed in order from the substrate, and a recess is provided in a region of the buffer layer opposite the semiconductor layer such that the protruding portion is disposed in the recess.

According to the above methods for producing a thin-film transistor, the lyophobic layer is formed on the gate insulating film (or the buffer layer), the recess is formed in the gate insulating film (or the buffer layer), and the opening (first opening) of the lyophobic layer is made larger than the recess (that is, the second opening is formed). Accordingly, the semiconductor layer formed thereafter can be made thicker in the inner region thereof and thinner near the ends thereof. This allows formation of a pattern of semiconductor layer corresponding to the planar shape of the lyophilic region and inhibits formation of projections at the ends of the semiconductor layer in a step of drying the semiconductor layer, thus preventing disconnection of the source/drain electrodes formed on the semiconductor layer. The thin-film transistor thus produced achieves superior switching characteristics and a higher yield.

### BRIEF DESCRIPTION OF THE DRAWINGS

FIG. 1 is a sectional view of a thin-film transistor according to a first embodiment of the present invention;

FIG. 2 is a bottom view of a semiconductor layer of the thin-film transistor;

FIGS. 3A and 3B are sectional views of a thin-film transistor serving as a comparative example;

FIG. 4 is a characteristic diagram showing the relationship between the height of a lyophilic region and the height of projections;

FIGS. 5A to 5D are sectional views showing some steps of a method for producing the thin-film transistor in FIG. 1;

FIGS. 6A to 6C are sectional views showing steps following the steps in FIGS. 5A to 5D;

FIGS. 7A to 7C are sectional views showing steps following the steps in FIGS. 6A to 6C;

FIG. 8 is a sectional view of a thin-film transistor according to a second embodiment of the present invention;

FIGS. 9A to 9C are sectional views showing some steps of a method for producing the thin-film transistor in FIG. 8;

FIGS. 10A to 10C are sectional views showing steps following the steps in FIGS. 9A to 9C;

FIGS. 11A and 11B are sectional views of thin-film transistors according to a first variation;

FIGS. 12A to 12D are sectional views showing a method for forming a lyophobic layer according to a second variation;

FIGS. 13A to 13D are sectional views showing a method for forming a lyophobic layer according to a third variation;

FIG. 14 is a diagram of an example of the configuration of a display unit;

FIG. 15 is an equivalent circuit diagram of an example of a pixel drive circuit shown in FIG. 10;

FIG. 16 is a schematic plan view of a module including the display unit;

FIG. 17 is a perspective view of a first application of the display unit;

FIGS. 18A and 18B are front and rear perspective views, respectively, of a second application;

FIG. 19 is a perspective view of a third application;

FIG. 20 is a perspective view of a fourth application; and

FIGS. 21A and 21B are front and side views, respectively, of a fifth application in an open state, and

FIGS. 21C to 21G are front, left side, right side, top, and bottom views, respectively, of the fifth application in a closed state.

### DESCRIPTION OF THE PREFERRED EMBODIMENTS

Embodiments of the present invention will now be described with reference to the drawings. The description will be given in the following order:

1. First embodiment

(1-1) Bottom-gate thin-film transistor

(1-2) Method for producing bottom-gate thin-film transistor

2. Second embodiment

(2-1) Top-gate thin-film transistor

(2-2) Method for producing top-gate thin-film transistor

### 1. First Embodiment

### (1-1) Bottom-Gate Thin-Film Transistor

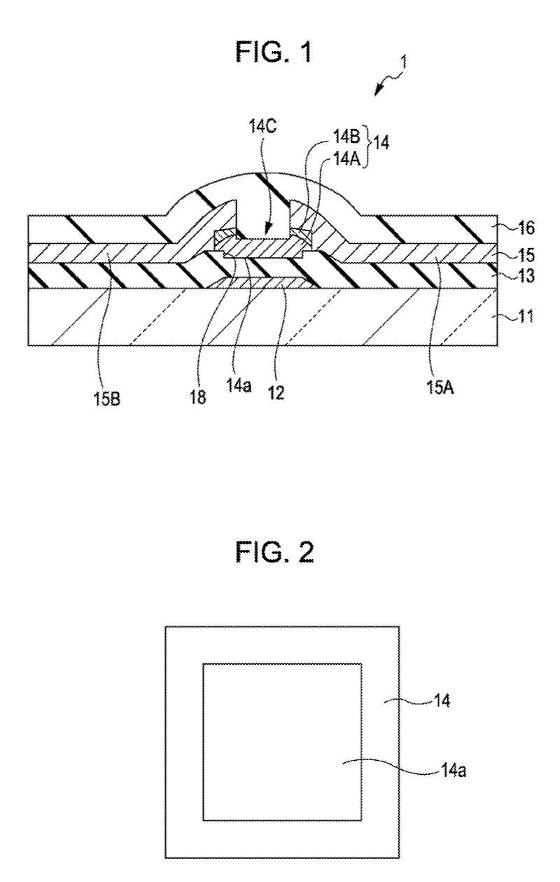

FIG. 1 shows the sectional structure of a bottom-gate thin-film transistor (TFT) 1 according to a first embodiment of the present invention. The TFT 1 includes a gate electrode 12, a gate insulating film 13, a semiconductor layer 14 including a channel layer 14A, source/drain electrodes 15 (15A and 15B), and a protective film 16 that are disposed on a substrate 11.

The substrate 11 is, for example, a glass substrate, although it may instead be a substrate of a material such as synthetic quartz, silicon, metal, resin, or resin film.

The gate electrode 12 controls the electron density of the channel layer 14A with a gate voltage applied to the TFT 1 and is formed of a metal such as chromium (Cr), molybdenum (Mo), or aluminum (Al).

The gate insulating film 13 is formed of an insulating material containing, for example, silicon (Si). The gate insulating film 13 covers the gate electrode 12. In this embodiment, the gate insulating film 13 is a silicon nitride (SiNₓ) film formed over the entire surface of the substrate 11, including the gate electrode 12. A recess 18 rectangular in cross section is provided in the top surface of the gate insulating film 13 in a region opposite the gate electrode 12. The recess 18 has a depth H of, for example, 200 nm, although the depth H is not limited thereto and may be selected within the range of 10 to 1,000 nm.

The channel layer 14A included in the semiconductor layer 14 is formed so as to cover the recess 18 and a region surrounding the recess 18. The channel layer 14A is located opposite the gate electrode 12 with the gate insulating film 13 therebetween. A contact layer 14B is disposed on the channel layer 14A. The contact layer 14B is divided into two left and right regions by etching, each region electrically connected to either source/drain electrode 15A or 15B. The channel layer 14A includes a channel region 14C between the source/drain electrodes 15A and 15B.

The channel layer 14A is formed by applying a liquid organic semiconductor material so as to form a layer by, for example, ink sliding, and drying the layer. The organic semiconductor material used is, for example, but not limited to, a liquid silicon material containing cyclopentasilane (CPS).

The contact layer 14B is formed of, for example, amorphous silicon doped with phosphorus (P). Although the channel layer 14A and the contact layer 14B are stacked together as the semiconductor layer 14 in this embodiment, the channel layer 14A and the contact layer 14B may be formed within the same layer.

In this embodiment, a portion of the channel layer 14A of the semiconductor layer 14 is disposed in the recess 18. That is, the channel layer 14A includes a protruding portion 14a protruding from an inner region of the surface (bottom surface), opposite the substrate 11, of the semiconductor layer 14 toward the substrate 11. The term “inner region” herein refers to a region of the bottom surface of the semiconductor layer 14 excluding a region near the ends thereof, and the term “near the ends” herein refers to a region extending a predetermined distance, for example, 1 to 5 μm, inward from the ends of the semiconductor layer 14. The protruding portion 14a is provided in the inner region to inhibit formation of projections at the ends of the semiconductor layer 14 in a step of drying the semiconductor layer 14, as described later, thus preventing disconnection of the source/drain regions 15A and 15B. Accordingly, the region “near the ends” includes at least regions of the bottom surface of the semiconductor layer 14 opposite contact regions of the source/drain regions 15A and 15B. That is, the region “near the ends” may be part of the periphery of the bottom surface of the semiconductor layer 14 or may be the entire periphery thereof.

FIG. 2 is a bottom view of the semiconductor layer 14, where the rectangular protruding portion 14a is provided in the inner region of the bottom surface of the rectangular semiconductor layer 14. Because the protruding portion 14a (in other words, the recess 18 of the gate insulating film 13) is formed, the semiconductor layer 14 is thicker in the inner region thereof and is thinner near the ends (periphery) thereof. This inhibits formation of projections at the ends of the semiconductor layer 14 in the step of drying the semiconductor layer 14 in this embodiment. The details will be described later.

The source/drain electrodes 15 (15A and 15B) are disposed on the gate insulating film 13 in contact with part of the semiconductor layer 14 (channel layer 14A). The source/drain electrodes 15A and 15B are formed of, for example, chromium (Cr), although it may instead be formed of, for example, a metal such as molybdenum (Mo), aluminum (Al), or titanium (Ti), or a multilayer film thereof.

The protective film 16 is formed on the source/drain electrodes 15A and 15B and the channel region 14C using, for example, the same material as the gate insulating film 13.

In the TFT 1, thus configured, according to this embodiment, the recess 18 is provided in the lyophilic gate insulating film 13, and the semiconductor layer 14, including the channel layer 14A, is formed in the recess 18 and the region surrounding the recess 18. Accordingly, the effect of surface tension in the lyophilic region, including the recess 18 and the region surrounding the recess 18, facilitates pattern formation, thus providing a higher manufacturing yield and a more uniform film thickness distribution.

The effect of inhibiting formation of projections at the ends of the semiconductor layer 14 in this embodiment will be described with reference to the case where a semiconductor layer is formed only in the recess 18 as a comparative example.

In this type of TFT production process, the formation of a liquid organic semiconductor is followed by a drying step (firing step). The inventors have experimentally demonstrated that projections are formed near the ends of the recess 18 in the drying step in the comparative example where the semiconductor layer is formed only in the recess 18. These projections may disconnect the source/drain electrodes 15 when they are formed on the semiconductor layer 14.

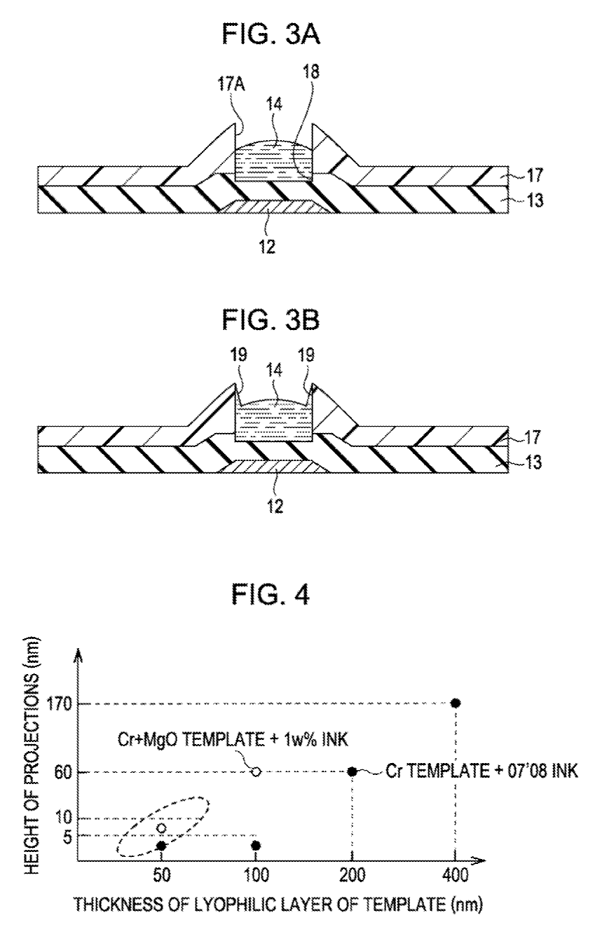

Specifically, the relationship between the shape of the recess 18 formed in the gate insulating film 13 and the drying process of the semiconductor layer 14 will be described with reference to FIGS. 3A, 3B, and 4.

To form an excellent pattern of liquid organic semiconductor material, as shown in FIG. 3A, a surface-fluorinated lyophobic layer 17 is formed as a bank on the gate insulating film 13 in the step of forming the semiconductor layer 14. An opening 17A is then formed in the lyophobic layer 17 by etching, and the recess 18 is formed in the gate insulating film 13 by etching. A lyophilic region is provided in the side and bottom surfaces of the recess 18 by the gate insulating film 13. The term “lyophobic” herein refers to having a low affinity to the liquid semiconductor material, for example, a surface free energy of 30 mJ/m² or less. On the other hand, the gate insulating film 13, which is formed of an insulating material containing silicon, has a higher affinity to the liquid semiconductor material than the lyophobic layer 17, for example, a surface free energy of 50 mJ/m² or more. Accordingly, the gate insulating film 13 is lyophilic to the liquid semiconductor material.

The lyophilic region provided in the bottom and side surfaces of the recess 18 and the lyophobic region provided around the recess 18 allow formation of an accurate pattern of liquid semiconductor material corresponding to the planar shape of the recess 18. For ink sliding, patterning characteristics can be improved as the height of the side surfaces of the lyophilic region in the recess 18 is increased. However, if the height of the side surfaces of the lyophilic region (i.e., the thickness of the semiconductor layer 14 within the recess 18) is increased, projections 19 are formed at the ends of the semiconductor layer 14, as shown in FIG. 3B.

FIG. 4 shows the relationship between the depth of the recess 18 (the height of the lyophilic region) and the height of the projections 19 formed at the ends of the semiconductor layer 14. FIG. 4 shows that the height of the projections 19 formed at the ends of the semiconductor layer 14 tends to increase as the height of the lyophilic region is increased. This tendency results from the “coffee stain” phenomenon. That is, in the drying process, the liquid semiconductor applied into the recess 18 dries faster at the ends thereof so that the undried liquid semiconductor flows outward. The liquid semiconductor then flows so as to cover the surface of the solidified semiconductor beyond the height of the lyophilic region (the depth of the recess 18), thus reaching the lyophobic region. As a result, the projections 19 are formed. These projections 19 may disconnect the source/drain electrodes 15A and 15B when they are formed on the semiconductor layer 14.

In this embodiment, by contrast, an excellent pattern can be achieved while effectively inhibiting formation of such projections. That is, because the height of projections formed at the ends of the semiconductor layer 14 tends to increase as the thickness of the lyophilic region is increased, as described above, the portion of the gate insulating film 13 opposite the semiconductor layer 14 is made thinner in the inner region of the semiconductor layer 14 and is made thicker near the ends thereof. In other words, whereas the recess 18 is formed in the entire region opposite the bottom surface of the semiconductor layer 14 in the comparative example, the recess 18 is formed only in the region opposite the inner region of the semiconductor layer 14 in this embodiment. This inhibits formation of projections in the drying step, thus achieving an excellent pattern of liquid semiconductor material.

### (1-2) Method for Producing Bottom-Gate Thin-Film Transistor

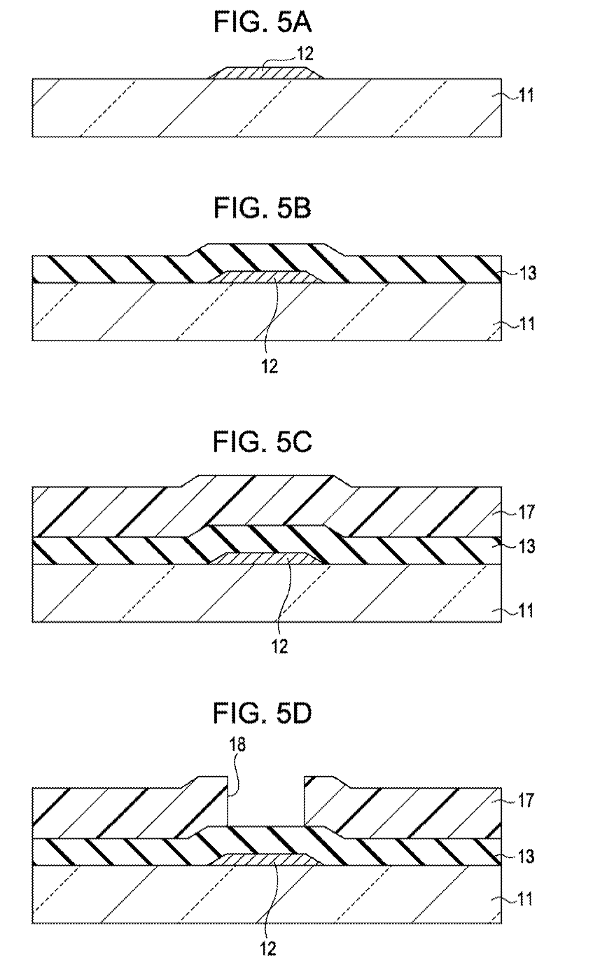

A method for producing the TFT 1 will be specifically described below with reference to FIGS. 5A to 5D, 6A to 6C, and 7A to 7C.

First, as shown in FIG. 5A, for example, a gate electrode 12 of chromium having a thickness of 200 nm is formed on a glass substrate 11. Specifically, a chromium film having a thickness of 200 nm is formed on one surface of the glass substrate 11 by, for example, sputtering, and is etched into a predetermined pattern (island-like pattern) by, for example, photolithography and etching.

Next, for example, a gate insulating film 13 of silicon nitride (SiNₓ) having a thickness of 500 nm is formed on the glass substrate 11 so as to cover the gate electrode 12 by plasma-enhanced CVD (FIG. 5B). Next, for example, a lyophobic layer 17 of a fluoropolymer, such as CYTOP® (manufactured by Asahi Glass Co., Ltd.), having a thickness of 300 nm is formed on the gate insulating film 13, and the surface of the lyophobic layer 17 is roughened by reactive ion etching (RIE) with oxygen plasma (FIG. 5C).

Next, a resist pattern (not shown) having an opening corresponding to the gate electrode 12 is formed on the lyophobic layer 17. The resist pattern is then used as a mask to selectively remove the lyophobic layer 17 by, for example, RIE with oxygen plasma. As a result, the opening 17A (first opening) is formed in the lyophobic layer 17 in a region opposite the gate electrode 12 so that the surface of the gate insulating film 13 is exposed in the opening 17A (FIG. 5D).

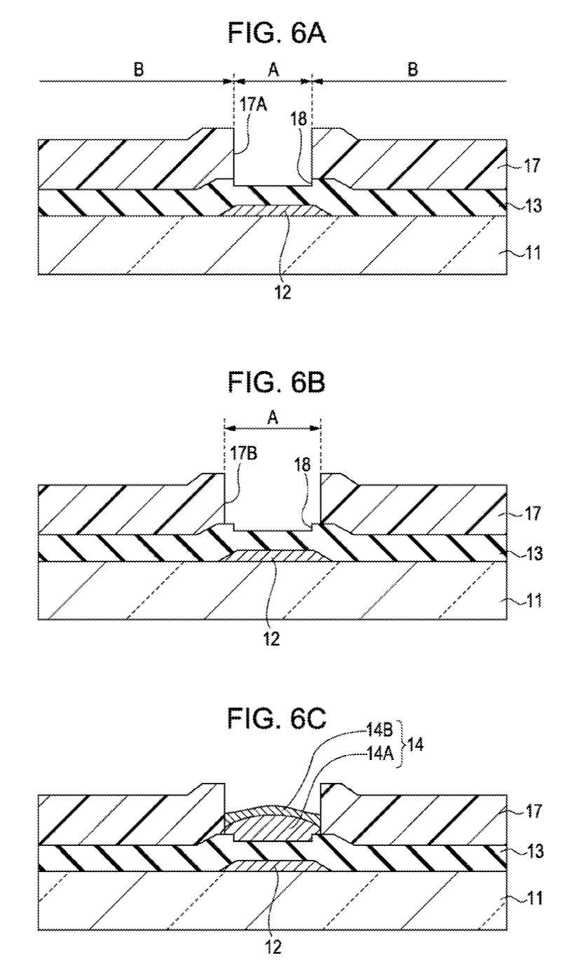

Next, using the same resist pattern as a mask, the recess 18 is formed by removing the gate insulating film 13 to a depth of, for example, 200 nm with a plasma of CF₄, oxygen, and argon (FIG. 6A). After the resist pattern is removed, the lyophobic layer 17 is heated (for example, at about 150° C. for ten minutes) to restore the lyophobicity of the roughened top surface of the lyophobic layer 17. Thus, a lyophilic region A is formed in a region corresponding to the bottom and side surfaces of the recess 18, and a lyophobic region B is formed in a region surrounding the recess 18 by the lyophobic layer 17.

Next, the lyophilic region A is widened by making the opening 17A of the lyophobic layer 17 larger than the recess 18 so that the portion of the gate insulating film 13 around the recess 18 is exposed (FIG. 6B). Specifically, an opening 17B (second opening) larger than the opening 17A is formed by the same process as the opening 17A is formed in the lyophobic layer 17 except that a resist pattern having an opening larger than the opening 17A is used. For example, the opening 17B is 1 μm or more, preferably 5 μm, larger than the recess 18 laterally from the ends thereof. After the resist pattern is removed, the lyophobic layer 17 is heated (for example, at about 150° C. for ten minutes) to restore the lyophobicity of the roughened top surface of the lyophobic layer 17.

Next, the semiconductor layer 14 (channel layer 14A and contact layer 14B) is formed in the recess 18 and the opening 17B surrounded by the lyophobic layer 17 (FIG. 6C). Specifically, for example, cyclopentasilane (CPS) is used as a liquid semiconductor material, with the molecular weight thereof adjusted to 5,000 to 1,000,000 by irradiation with ultraviolet light having a wavelength of 365 nm. Printing is performed using a CPS monomer solution diluted to a concentration of 30% by weight. The printing method used is, for example, ink sliding. In this case, the liquid semiconductor is mostly repelled and removed from a region in contact with the lyophobic layer 17 and is therefore applied to the lyophilic region A, including the recess 18 and the region surrounding the recess 18, where the gate insulating film 13 is exposed.

Through the step described above, a pattern of liquid silicon material corresponding to the planar shape of the lyophilic region A, including the recess 18 and the region surrounding the recess 18, is formed. The pattern is then dried, for example, at 400° C. for one hour, to form a channel layer 14A of amorphous silicon having a thickness of 200 nm. Next, for example, a contact layer 14B of phosphorus-doped amorphous silicon having a thickness of 50 nm is formed on the channel layer 14A by plasma-enhanced CVD. The lyophobic layer 17 is then removed by RIE with oxygen plasma.

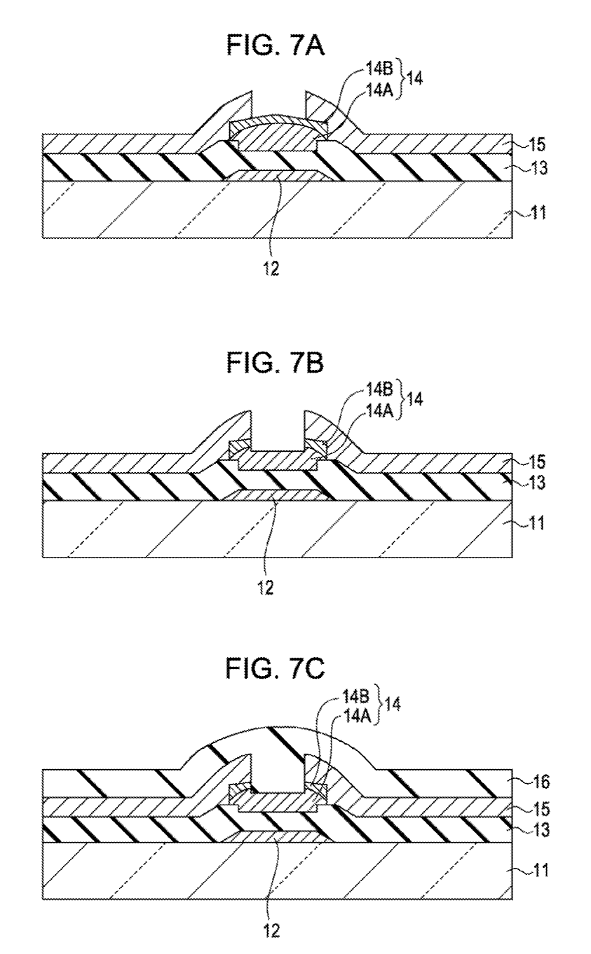

Next, the pair of source/drain electrodes 15 (15A and 15B) are formed so as to cover the periphery of the contact layer 14B and the gate insulating film 13. Specifically, for example, a chromium film having a thickness of 200 nm is formed so as to cover the contact layer 14B and the gate insulating film 13 in the entirety thereof by sputtering and is etched by photolithography and etching to form an opening in the chromium film so that contact layer 14B is exposed therein (FIG. 7A). Next, the portion of the contact layer 14B exposed between the source/drain electrodes 15 is removed with a plasma of CF₄, oxygen, and argon to form the channel region 14C (FIG. 7B).

Next, the protective film 16 is formed on the source/drain electrodes 15 and the channel region 14C (FIG. 7C). Specifically, for example, a SiNₓ film having a thickness of 300 nm is formed by plasma-enhanced CVD and is etched into a predetermined pattern by photolithography and dry etching. Thus, the bottom-gate TFT 1 shown in FIG. 1 is completed.

In this embodiment, as described above, the recess 18 is provided in the region of the gate insulating film 13 opposite the gate electrode 12. In addition, the lyophilic region A is formed in the region including the recess 18 and the region surrounding the recess 18, and the lyophobic region B is formed in the region surrounding the lyophilic region A by the lyophobic layer 17. This allows formation of an accurate pattern of semiconductor layer 14 corresponding to the planar shape of the lyophilic region A including the recess 18.

In this embodiment, additionally, the recess 18 is provided in the region of the gate insulating film 13 opposite the inner region of the semiconductor layer 14 so that the semiconductor layer 14 is thicker in the inner region thereof and is thinner near the ends (periphery) thereof in the drying step (FIG. 6C). This inhibits formation of projections near the ends of the channel layer 14A, thus preventing disconnection of the source/drain electrodes 15A and 15B formed on the semiconductor layer 14. Accordingly, the TFT 1 achieves superior switching characteristics and a higher yield. For example, the TFT 1 has superior switching characteristics including a mobility of 0.01 cm/Vs and an on/off ratio of 10⁷.

### 2. Second Embodiment

Next, a top-gate TFT and a method for producing the top-gate TFT according to a second embodiment of the present invention will be described, where the same structural portions as in the first embodiment are denoted by the same reference numerals, and a description thereof will be omitted.

### (2-1) Top-Gate Thin-Film Transistor

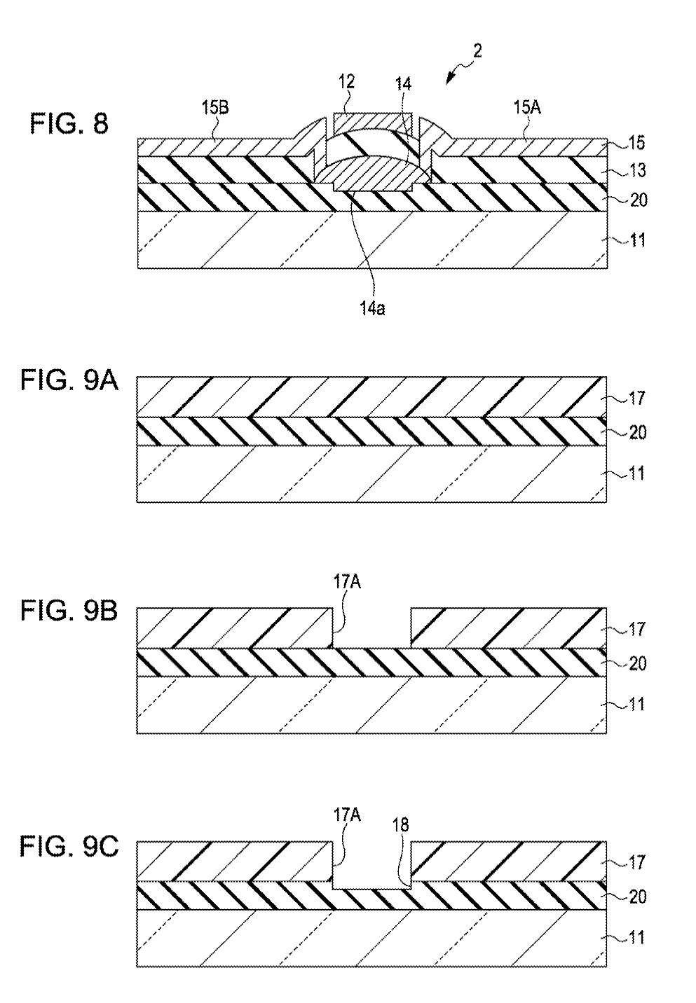

As shown in FIG. 8, a top-gate TFT 2 according to this embodiment includes a buffer layer (insulating film) 20, a semiconductor layer 14, a gate insulating film 13, a pair of source/drain electrodes 15 (15A and 15B), and a gate electrode 12 that are stacked on a substrate 11 in the above order. The source/drain electrodes 15A and 15B extend through the gate insulating film 13 to reach a contact layer 14B of the semiconductor layer 14. The buffer layer 20 is formed of, for example, the same material as the gate insulating film 13 in the first embodiment.

In the TFT 2, a recess 18 is provided in a region of the buffer layer 20 under the semiconductor layer 14, and a protruding portion 14a protrudes from an inner region of the bottom surface of the semiconductor layer 14 toward the substrate 11. Accordingly, in this embodiment, a lyophilic region A is provided in a region including the recess 18 and a region surrounding the recess 18, and a lyophobic region B is provided in a region surrounding the lyophilic region A by a lyophobic layer 17. This allows formation of an accurate pattern of semiconductor layer 14 corresponding to the planar shape of the lyophilic region A and also inhibits formation of projections near the ends of the channel layer 14A in a drying step.

### (2-2) Method for Producing Top-Gate Thin-Film Transistor

First, as shown in FIG. 9A, for example, a buffer layer 20, having a thickness of 500 nm, of the same material as the gate insulating film 13 is formed on a glass substrate 11 by sputtering. Next, for example, a lyophobic layer 17 of a fluoropolymer, such as CYTOP®, having a thickness of 300 nm is formed on the buffer layer 20, and the surface of the lyophobic layer 17 is roughened by RIE with oxygen plasma.

Next, a resist pattern (not shown) having an opening corresponding to the gate electrode 12, described later, is formed on the lyophobic layer 17. The resist pattern is then used as a mask to selectively remove the lyophobic layer 17 by, for example, RIE with oxygen plasma. As a result, an opening 17A is formed in the lyophobic layer 17 in a region opposite the gate electrode 12 so that the surface of the buffer layer 20 is exposed in the opening 17A (FIG. 9B).

Next, using the same resist pattern as a mask, the recess 18 is formed in the buffer layer 20 by removing the buffer layer 20 to a depth of, for example, 200 nm with a plasma of CF₄, oxygen, and argon. After the resist pattern is removed, the lyophobic layer 17 is heated (for example, at about 150° C. for ten minutes) to restore the lyophobicity of the roughened top surface of the lyophobic layer 17. Thus, the lyophilic region A is formed in a region corresponding to the bottom and side surfaces of the recess 18, and the lyophobic region B is formed in a region surrounding the recess 18 by the lyophobic layer 17 (FIG. 9C).

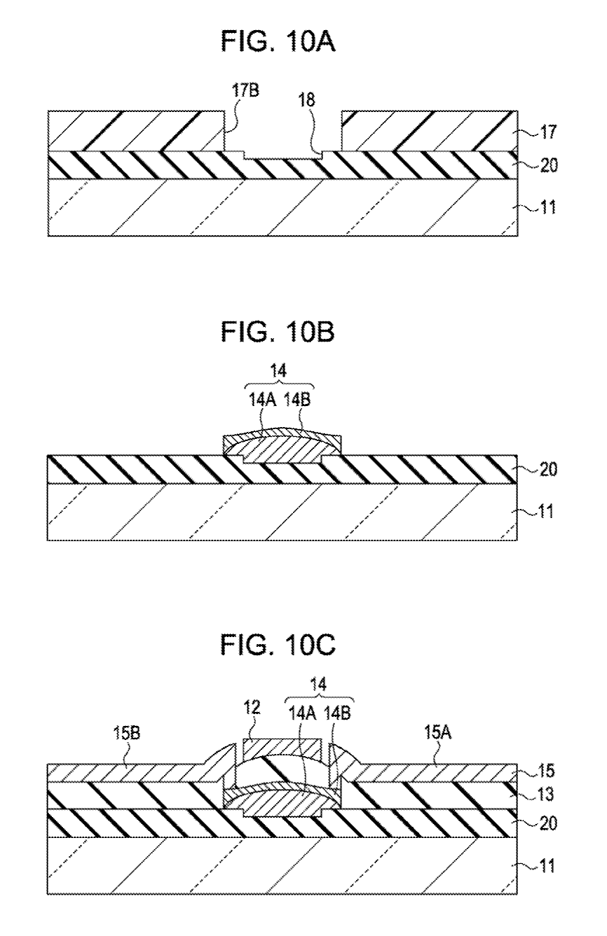

Next, the lyophilic region A is widened by making the opening 17A of the lyophobic layer 17 larger than the recess 18 so that the portion of the buffer layer 20 around the recess 18 is exposed (FIG. 10A). Specifically, an opening 17B larger than the opening 17A is formed by the same process as the opening 17A is formed in the lyophobic layer 17 except that a resist pattern having an opening larger than the opening 17A is used. For example, the opening 17B is 1 μm or more, preferably 5 μl, larger than the recess 18 laterally from the ends thereof. After the resist pattern is removed, the lyophobic layer 17 is heated (for example, at about 150° C. for ten minutes) to restore the lyophobicity of the roughened top surface of the lyophobic layer 17.

Next, the semiconductor layer 14 (channel layer 14A and contact layer 14B) is formed in the recess 18 and the opening 17B using the same materials and through the same process as in the first embodiment (FIG. 10B).

A pattern of liquid silicon material corresponding to the planar shape of the lyophilic region A, including the recess 18 and the region surrounding the recess 18, is formed. The pattern is then heated, for example, at 400° C. for one hour, to form a channel layer 14A of amorphous silicon having a thickness of 200 nm.

Next, for example, a contact layer 14B of phosphorus-doped amorphous silicon having a thickness of 50 nm is formed on the channel layer 14A by plasma-enhanced CVD. The lyophobic layer 17 is then removed by RIE with oxygen plasma.

Next, the gate insulating film 13 is formed on the semiconductor layer 14 and the buffer layer 20, and a pair of through-holes 13a and 13b are formed in the gate insulating film 13 so as to reach the contact layer 14B of the semiconductor layer 14. The pair of source/drain electrodes 15 (15A and 15B) are then formed so as to be electrically connected to the contact layer 14B via the through-holes 13a and 13b. Next, the gate electrode 12 is formed on the gate insulating film 13 in a region opposite the semiconductor layer 14. Thus, the top-gate TFT 2 shown in FIG. 9 is completed.

In this embodiment, the recess 18 is provided in the region corresponding to the gate electrode 12 in the same manner as in the first embodiment except that the recess 18 is provided in the buffer layer 20. In addition, the lyophilic region A is formed in the region including the recess 18 and the region surrounding the recess 18, and the lyophobic region B is formed in the region surrounding the lyophilic region A by the lyophobic layer 17. This allows formation of an accurate pattern of semiconductor layer 14 corresponding to the planar shape of the lyophilic region A including the recess 18.

In this embodiment, additionally, the recess 18 is provided in the region of the buffer layer 20 corresponding to the inner region of the semiconductor layer 14 so that the semiconductor layer 14 is thicker in the inner region thereof and is thinner near the ends (periphery) thereof in the drying step (FIG. 10B). This inhibits formation of projections near the ends of the channel layer 14A, as in the first embodiment, thus preventing disconnection of the source/drain electrodes 15A and 15B. Accordingly, the TFT 2 achieves superior switching characteristics and a higher yield.

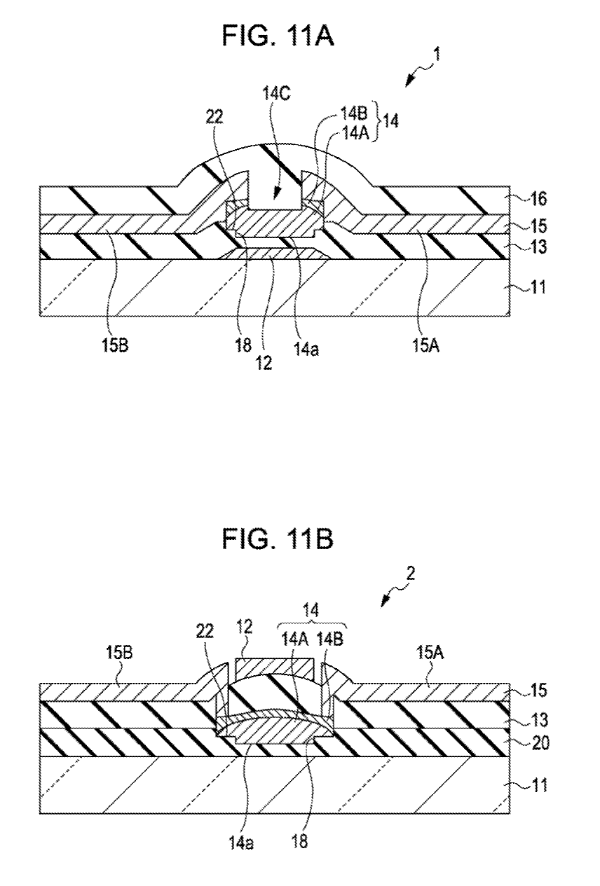

While the TFTs according to the first and second embodiments of the present invention have been described above, the present invention is not limited to the above embodiments; various modifications are permitted so long as the same advantages as in the above embodiments can be achieved. For example, the shape of the protruding portion 14a of the semiconductor layer 14, that is, the shape of the recess 18 provided in the gate insulating film 13 or the buffer layer 20, is not limited to a rectangular cross-sectional shape, but those shown in FIGS. 11A and 11B may instead be used.

That is, one or more steps 22 may be provided near the ends of the recess 18 of the gate insulating film 13 (FIG. 11A) or the buffer layer 20 (FIG. 11B). In this case, the protruding portion 14a of the semiconductor layer 14 has steps near the ends thereof. This allows formation of a finer pattern of semiconductor layer 14.

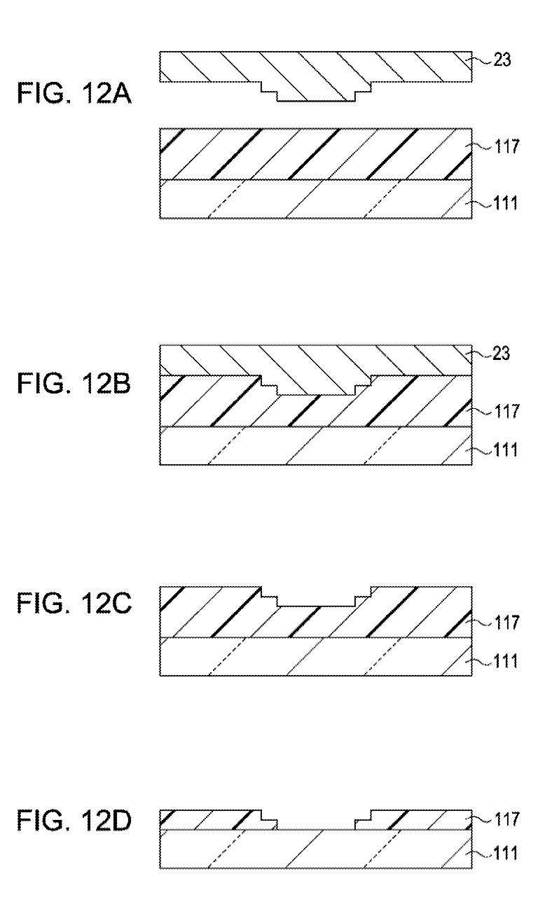

In addition, the method for forming the recess 18 is not limited to etching, as described above, but it may instead be formed by embossing, as shown in FIGS. 12A to 12D. Specifically, a lyophobic layer 117 is formed on the gate insulating film 13 and is pressed against a heated stepped mold 23 to form a stepped recess in the lyophobic layer 117. After unwanted residues are removed by dry etching, the gate insulating film 13 is etched by RIE using the lyophobic layer 17 as a mask to form the recess 18.

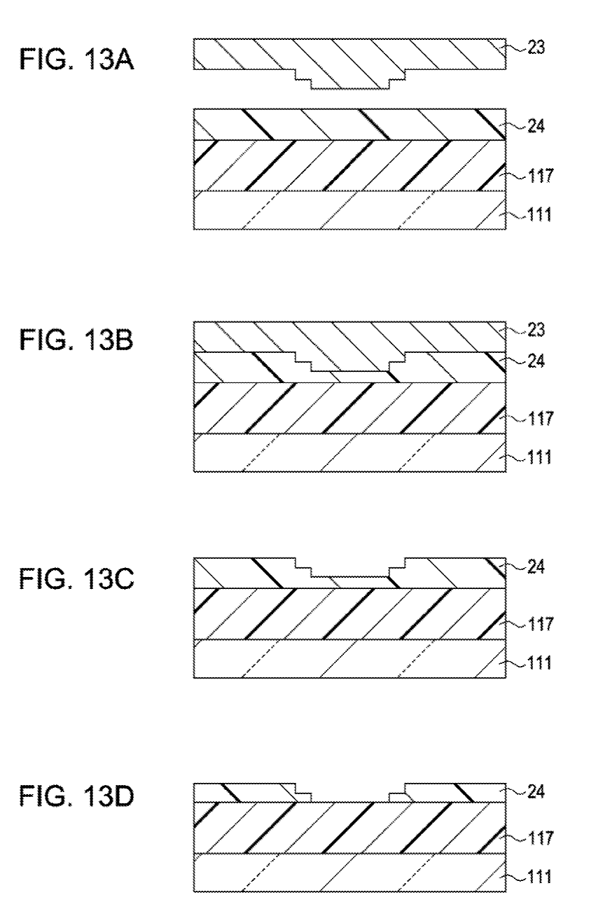

Alternatively, as shown in FIG. 13A to 13D, a resist layer 24 is formed on the lyophobic layer 117 on the gate insulating film 13 and is pressed against the heated stepped mold 23 to form a stepped recess in the resist layer 24. The lyophobic layer 117 and the gate insulating film 13 are then sequentially etched by RIE using the resist layer 24 having the stepped recess as a mask to form a recess 18 having a desired step.

Applications of the above TFT 1 (TFT 2) will now be described.

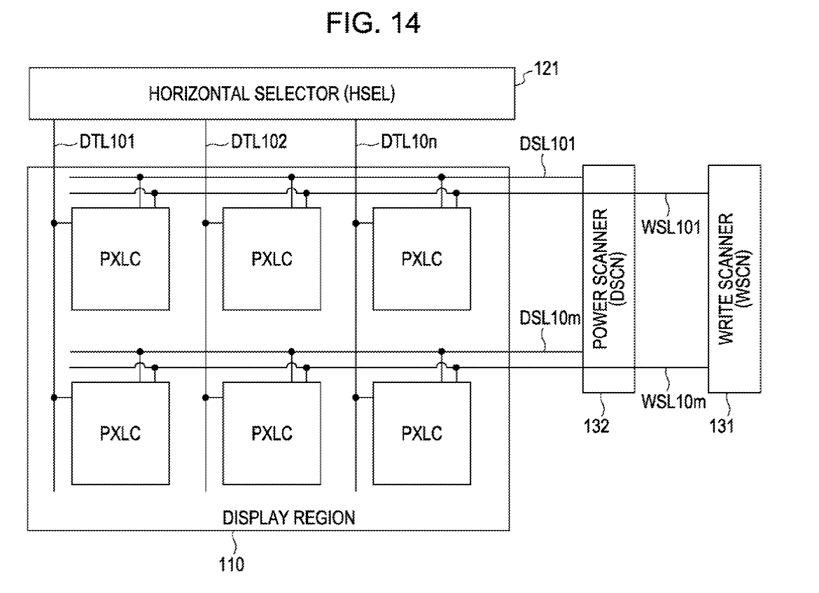

FIG. 14 shows the configuration of a display unit used as an ultrathin color organic light-emitting display. This display unit has, for example, a display region 110 in which pixels PXLC including organic light-emitting devices, serving as display devices, are arranged in a matrix on a TFT substrate 1, described later. The display region 110 is surrounded by a horizontal selector (HSEL) 121, serving as a signal section, a write scanner (WSCN) 131, serving as a scanner section, and a power scanner (DSCN) 132.

In the display region 110, signal lines DTL (DTL101 to DTL10n) extend in a column direction, and scan lines WSL (WSL101 to WSL10m) and power lines DSL (DSL101 to DSL10m) extend in a row direction. Pixel circuits 140 including the organic light-emitting devices (each including a red, green, or blue light-emitting device (subpixel)) are disposed at intersections of the signal lines DTL and the scan lines WSL. The signal lines DTL are connected to the horizontal selector 121, which supplies video signals to the signal lines DTL. The scan lines WSL are connected to the write scanner 131. The power lines DSL are connected to the power scanner 132.

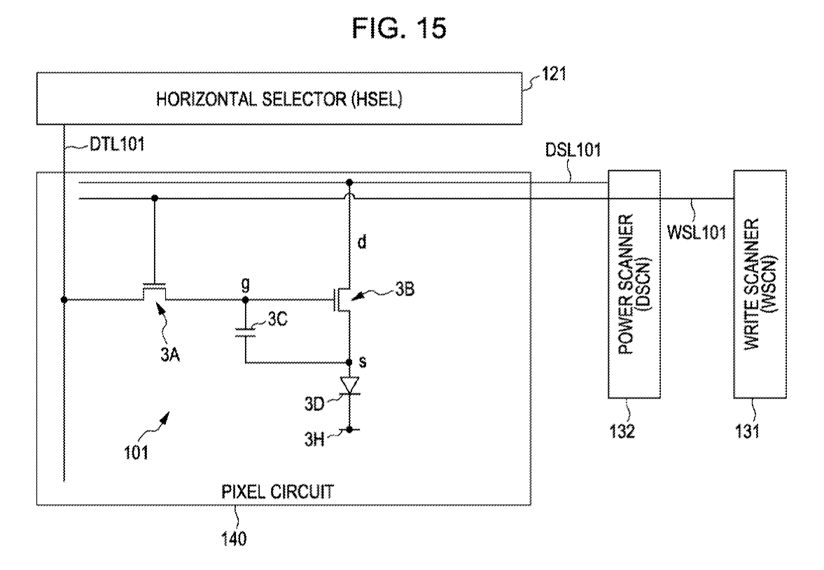

FIG. 15 shows an example of a pixel circuit 140. The pixel circuit 140 is an active drive circuit including a sampling transistor 3A, a drive transistor 3B, a hold capacitor 3C, and an organic light-emitting device 3D. The transistors 3A and 3B are each composed of the TFT 1 (TFT 2) described above.

The sampling transistor 3A has a gate thereof connected to the corresponding scan line WSL101, and also has either a source thereof or a drain thereof connected to the corresponding signal line DTL101 and the other connected to a gate g of the drive transistor 3B. The drive transistor 3B has a drain d thereof connected to the corresponding power line DSL101 and a source s thereof connected to an anode of the light-emitting device 3D. A cathode of the light-emitting device 3D is connected to a ground line 3H. The ground line 3H is shared by all pixels PXLC. The hold capacitor 3C is connected between the source s and the gate g of the drive transistor 3B.

The sampling transistor 3A becomes conducting in response to a control signal supplied from the scan line WSL101 and samples the signal potential of a video signal supplied from the signal line DTL101, the signal potential being held by the hold capacitor 3C. The drive transistor 3B is supplied with a current from the power line DSL101 at a first potential and supplies a drive current to the light-emitting device 3D depending on the signal potential held by the hold capacitor 3C. Being supplied with the drive current, the light-emitting device 3D emits light with a luminance depending on the signal potential of the video signal.

In the display unit, the sampling transistors 3A become conducting in response to control signals supplied from the scan lines WSL and sample the signal potentials of video signals supplied from the signal lines DTL, the signal potentials being held by the hold capacitors 3C. The drive transistors 3B are supplied with a current from the power lines DSL at a first potential and supply drive currents to the light-emitting devices 3D (red, green, and blue organic light-emitting devices) depending on the signal potentials held by the hold capacitors 3C. Being supplied with the drive currents, the light-emitting devices 3D emit light with luminances depending on the signal potentials of the video signals.

### Module and Applications

Next, applications of the display unit will be described. The display unit can be applied to a wide variety of electronic apparatuses for displaying an image or video with externally input video signals or internally generated video signals, including televisions, digital cameras, notebook personal computers, portable terminal devices such as cellular phones, and video cameras.

### Module

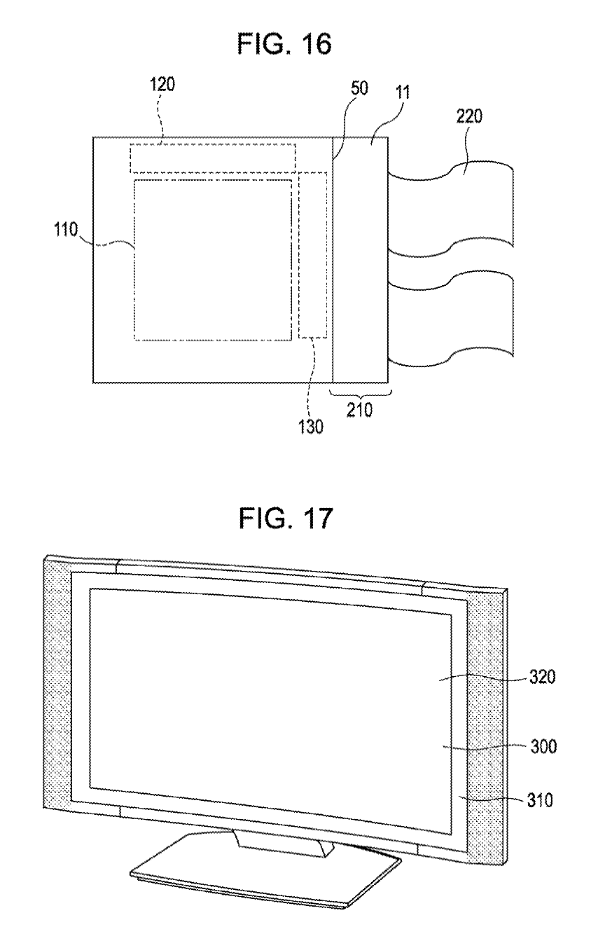

The above display unit can be built into various electronic apparatuses, including first to fifth applications described below, for example, as a module shown in FIG. 16. This module includes, for example, an exposed region 210 not covered by a sealing substrate 50 and an adhesive layer (not shown) on one side of a substrate 11 and external connection terminals (not shown) formed in the exposed region 210 by routing wiring lines from a signal-line drive circuit 120 and a scan-line drive circuit 130. The external connection terminals may be connected to a flexible printed circuit board (FPC) 220 for signal input/output.

### First Application

FIG. 17 shows the external appearance of a television including the above display unit. This television includes, for example, a video display screen 300 including a front panel 310 and a glass filter 320. The video display screen 300 includes the above display unit.

### Second Application

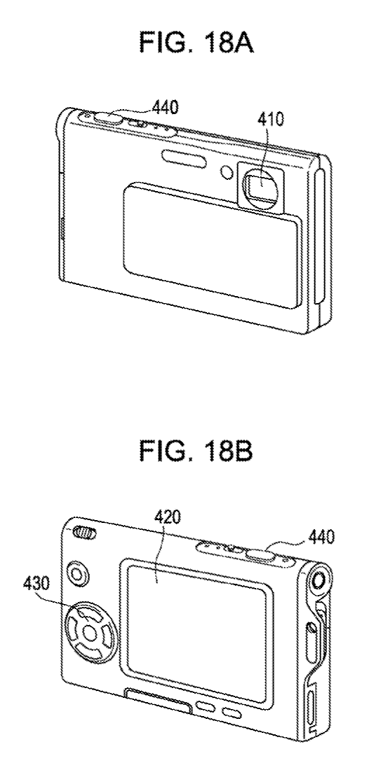

FIGS. 18A and 18B show the external appearance of a digital camera including the above display unit. This digital camera includes, for example, a flash 410, a display section 420, a menu switch 430, and a shutter button 440. The display section 420 includes the above display unit.

### Third Application

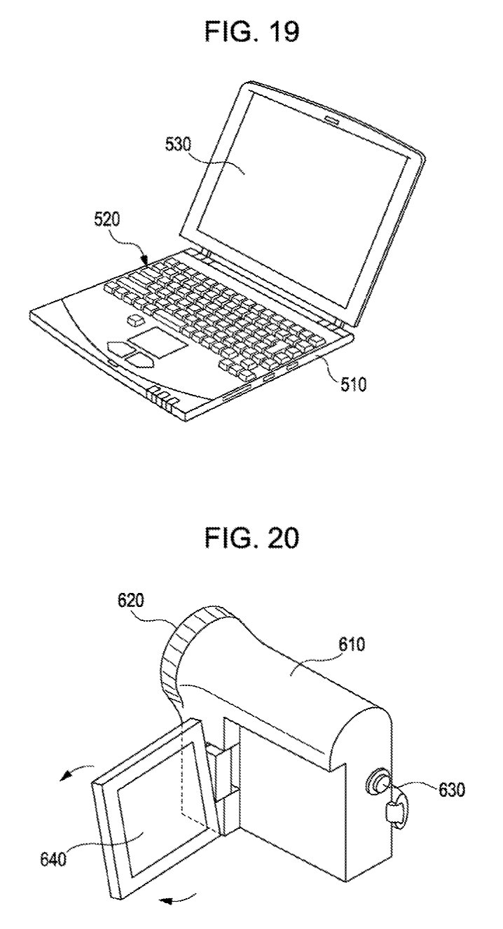

FIG. 19 shows the external appearance of a notebook personal computer including the above display unit. This notebook personal computer includes, for example, a main body 510, a keyboard 520 for inputting, for example, characters, and a display section 530 for displaying an image. The display section 530 includes the above display unit.

### Fourth Application

FIG. 20 shows the external appearance of a video camera including the above display unit. This video camera includes, for example, a main body 610, a lens 620 disposed in the front of the main body 610 to capture an image of a subject, a start/stop switch 630 for image capturing, and a display section 640. The display section 640 includes the above display unit.

### Fifth Application

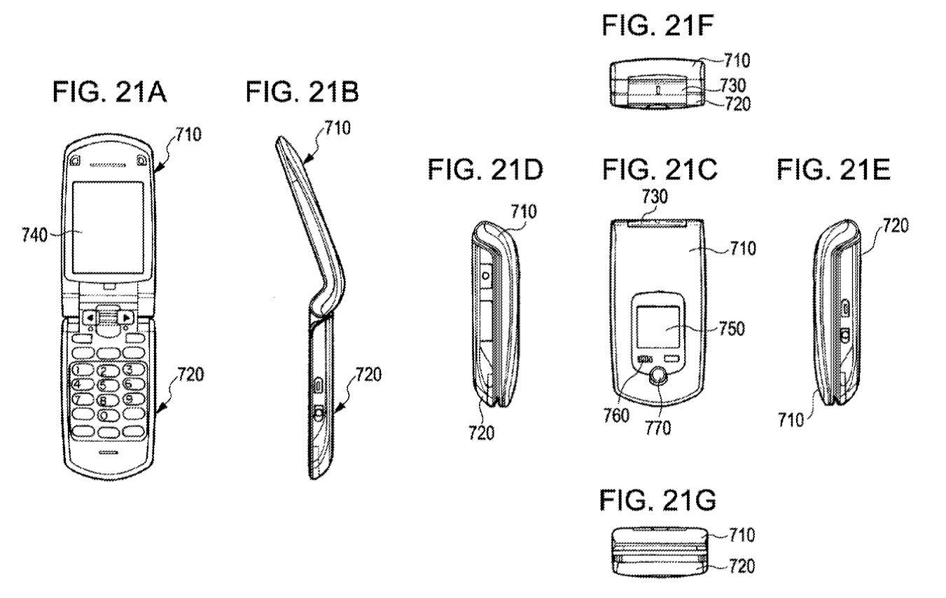

FIGS. 21A to 21G show the external appearance of a cellular phone including the above display unit. This cellular phone includes, for example, an upper casing 710, a lower casing 720, a coupling portion (hinge portion) 730 coupling the upper casing 710 and the lower casing 720, a display 740, a sub-display 750, a picture light 760, and a camera 770. The display 740 or the sub-display 750 includes the above display unit.

The present application contains subject matter related to that disclosed in Japanese Priority Patent Application JP 2009-147783 filed in the Japan Patent Office on Jun. 22, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin-film transistor comprising:
a gate electrode disposed on a substrate;
a semiconductor layer formed of an organic semiconductor and constituting a channel region, the semiconductor layer including a protruding portion protruding toward the substrate from an inner region of a surface, opposite the substrate, of the semiconductor layer excluding a region near ends thereof;
a gate insulating film disposed between the gate electrode and the semiconductor layer; and
a pair of source/drain electrodes electrically connected to the semiconductor layer;

2. The thin-film transistor according to claim 1, wherein the gate electrode, the gate insulating film, and the semiconductor layer are disposed in order from the substrate, a recess being provided in a region of the gate insulating film opposite the semiconductor layer such that the protruding portion is disposed in the recess.

3. The thin-film transistor according to claim 1, further comprising a buffer layer, wherein the buffer layer, the semiconductor layer, the gate insulating film, and the gate electrode are disposed in order from the substrate, a recess being provided in a region of the buffer layer opposite the semiconductor layer such that the protruding portion is disposed in the recess.

4. The thin-film transistor according to claim 2 or 3, wherein the semiconductor layer includes a channel layer of an organic semiconductor and a contact layer disposed thereon, the pair of source/drain electrodes being in contact with the contact layer.

5. A method for producing a thin-film transistor, comprising the steps of:
forming a gate electrode and a gate insulating film on a substrate in the stated order;
forming a lyophobic layer on the gate insulating film, forming a first opening in the lyophobic layer, and forming a recess having the same size as the first opening in the gate insulating film;
forming a second opening in the lyophobic layer by widening the first opening;
forming a semiconductor layer of a liquid organic semiconductor in the recess of the gate insulating film and the second opening of the lyophobic layer;
drying the semiconductor layer and removing the lyophobic layer; and
forming a pair of source/drain electrodes in contact with the semiconductor layer.

6. A method for producing a thin-film transistor, comprising the steps of:
forming a buffer layer of an insulating material on a substrate;
forming a lyophobic layer on the buffer layer, forming a first opening in the lyophobic layer, and forming a recess having the same size as the first opening in the buffer layer;
forming a second opening in the lyophobic layer by widening the first opening;
forming a semiconductor layer of a liquid organic semiconductor in the recess of the buffer layer and the second opening of the lyophobic layer;
drying the semiconductor layer and removing the lyophobic layer;
forming a gate insulating film on the buffer layer and the semiconductor layer; and
forming a pair of through-holes reaching the semiconductor layer in the gate insulating film and forming a pair of source/drain electrodes in contact with the semiconductor layer via the through-holes.

7. The method for producing a thin-film transistor according to claim 5 or 6, wherein the second opening formed in the lyophobic layer is at least 1 μm wider than the first opening.

8. The method for producing a thin-film transistor according to claim 5 or 6, wherein the lyophobic layer is formed of a fluoropolymer capable of being applied.
